(19) United States
(12) Patent Application Publication
(10) Pub. No.: US 2018/0248092 A1
(43) Pub. Date: Aug. 30, 2018

(54) LIGHT SENSOR LEAD FRAME SUBSTRATE AND MANUFACTURING METHOD THEREOF

(71) Applicant: Jen-You Liang, Changhua (TW)

(72) Inventor: Jen-You Liang, Changhua (TW)

(73) Assignee: TTOP CORP., CHANGHUA (TW)

(21) Appl. No.: 15/900,685

(22) Filed: Feb. 20, 2018

(30) Foreign Application Priority Data
Feb. 24, 2017 (TW) 106106393

(51) Int. Cl. H01L 33/62; H01L 33/60; H05K 1/03; H05K 1/18

(52) U.S. Cl. CPC H01L 33/62; H01L 33/60; H05K 1/03; H05K 2201/10522; H05K 2201/10227; H05K 2201/1053; H05K 1/181

(57) ABSTRACT

A light sensor lead frame substrate may comprise a plurality of lead frame substrates formed on a metal substrate through a series of processing including chemical etching, plasma etching and stamping. The lead frame substrates are connected through a plurality of connecting sections, and each of the lead frame substrates is connected to the metal substrate through the connecting section. Each of the connecting sections has two pre-cut sections respectively formed at two ends of the connecting section. After molding, the lead frame substrates are configured to pass through a series of processing including electroplating, injection and desmear to enable each of the lead frame substrates to have a first insulating layer, a reflector cup and a second insulating layer, and with the pre-cut sections, the connecting sections are adapted to be easily washed down by a punch in the punching process.

### FIELD OF THE INVENTION

The present invention relates to a light sensor lead frame substrate and manufacturing method thereof and more particularly to a cost-saving light sensor lead frame substrate.

### BACKGROUND OF THE INVENTION

Referring to FIGS. 11 and 12, a conventional light sensor lead frame substrate comprises a plurality of first lead frame substrates (30) which are formed on a first metal substrate (3) through a series of processing including chemical etching, plasma etching and stamping. Thereafter, the first lead frame substrates (30) are configured to pass through another series of processing including electroplating, injection and desmear processing to enable each of the first lead frame substrates (30) to have a first insulating layer (31) and a first reflector cup (32). The first reflector cup (32) has a flat first bottom portion (321) which is adapted to directly contact to a top surface of the first lead frame substrate (30). Moreover, the first insulating layer (31) is attached on the first lead frame substrate (30) to enable a second edge (311) of the first insulating layer (31), a first edge (301) of the first lead frame substrate (30) and the first bottom portion (321) of the first reflector cup (32) to be on the same plane. After the light sensor lead frame substrate is packaged, each of the first lead frame substrates (30) having a LED is cut down from the first metal substrate (3).

However, the above conventional light sensor lead frame substrate is disadvantageous because: (i) before cut down from the first metal substrate (3), the first lead frame substrates (30) are electrically connected and cannot be tested, which increases greater probability of the products having errors on brightness or color temperature; (ii) cutting process is completed through the cutting machine which needs higher cost than the conventional stamping machine; and (iii) after been cut, each of the first lead frame substrates (30) is configured to form a plurality of exposed metal portions (302) (as shown in FIGS. 11 and 14) which enable moisture in the air to directly infiltrate into the first reflector cup (32) (as shown in FIG. 13), resulting in reducing the lifetime of the light sensor lead frame substrate.

Referring to FIGS. 15 and 16, another light sensor lead frame substrate comprises a plurality of second lead frame substrates (40) which are formed on a second metal substrate (4) through a series of processing including chemical etching, plasma etching and stamping. Thereafter, the second lead frame substrates (40) is adapted to pass through another series of processing including electroplating, injection and desmear processing to enable each of the second lead frame substrates (40) to have a second insulating layer (41) and a second reflector cup (42). Moreover, the second reflector cup (42) has a flat second bottom portion (421) which is configured to directly contact to a top surface of the second lead frame substrate (40). Each of the second lead frame substrates (40) comprises two clamping portions (401) respectively at two lateral sides thereof, and the two clamping portions (401) are configured to respectively stick out of two lateral edges of the second reflector cup (42). After the light sensor lead frame substrate is packaged, each of the second lead frame substrates (40) having a LED is taken down from the second metal substrate (4) through stamping method.

However, the above conventional light sensor lead frame substrate is still disadvantageous because: (i) the clamping portions (401) increase the size of the second lead frame substrate (40), which decreases the total number of the second lead frame substrates (40) on the single second metal substrate (4); (ii) the clamping portions (401), similar to the exposed metal portions (302) of the first lead frame substrate (30), enable the moisture in the air to directly infiltrate into the second reflector cup (42) (as shown in FIGS. 17 and 18), resulting in reducing the lifetime of the light sensor lead frame substrate; and (iii) the connection type between the second bottom portion (421) and the second lead frame substrate (40) is different from that between the first bottom portion (321) and the first lead frame substrate (30), which leads that a single packaging equipment cannot be used for both of the two light sensor lead frame substrates (30)(40), which results that the manufacturing cost is increased or a manufacturer decides to not manufacture the second lead frame substrates (40). Therefore, there remains a need for a new and improved design for a light sensor lead frame substrate to overcome the problems presented above.

### SUMMARY OF THE INVENTION

The present invention provides a light sensor lead frame substrate which comprises a plurality of lead frame substrates formed on a metal substrate through a series of processing including chemical etching, plasma etching and stamping. The lead frame substrates are connected through a plurality of connecting sections, and each of the lead frame substrates is connected to the metal substrate through the connecting section. Moreover, each of the connecting sections between the lead frame substrates or between the lead frame substrate and the metal substrate has two pre-cut sections respectively formed at two ends of the connecting section. Each of the lead frame substrates comprises a first edge, and at least a protruding edge upwardly protrudes from a top end of the first edge. After molding, the lead frame substrates are configured to pass through a series of processing including electroplating, injection and desmear to enable each of the lead frame substrates to have a first insulating layer, a reflector cup and a second insulating layer, wherein the reflector cup is adapted to cover the protruding edge through the second insulating layer, and the second insulating layer is configured to extend outwardly to partially cover top surfaces of adjacent connecting sections. Additionally, each of the second insulating layers has a third edge while each of the first insulating layers comprises a second edge. Also, with the pre-cut sections, after the processing of electroplating, injection and desmear, the connecting sections are adapted to be easily washed down by a punch in the punching process. Furthermore, for the single lead frame substrate, with the second insulating layer partially covering the top surfaces of the adjacent connecting sections, the third edge of the second insulating layer is configured to be formed non-coplanar to the first edge of the lead frame substrate and the second edge of the first insulating layer which are in the same plane.

Comparing with conventional light sensor lead frame substrate, the present invention is advantageous because: (i) after the connecting sections are washed down, each of the lead frame substrates is weakly attached on the metal substrate through the second insulating layer thereof such that after the packaging, the lead frame substrates are easily taken down from the metal substrate through the punching processing or by fingers, which reduces the cost of production; (ii) after the connecting sections are washed down, the lead frame substrates are no longer connected, and each of the lead frame substrates can be pre-tested before taken from the metal substrate, which increases the product yield; (iii) without clamping portions, the total number of the lead frame substrates on the single metal substrate is increased; (iv) the moisture in the air has to pass through the protruding edges before infiltrating into the reflector cups, which prolongs the lifetime of the light sensor lead frame substrate; (v) each of the lead frame substrates has no clamping portions and excess exposed metal portions, which effectively reduces the moisture in the air from infiltrating into the reflector cup, thereby prolonging the lifetime of the light sensor lead frame substrate; and (vi) without clamping portions, the packaging process of the light sensor lead frame substrate of the present invention can be completed by a common packaging equipment, which can be widely accepted by manufacturers.

### BRIEF DESCRIPTION OF THE DRAWINGS

FIG. 1 is a plan view of a light sensor lead frame substrate of the present invention.

FIG. 2 is a partial enlarged drawing of the light sensor lead frame substrate of the present invention.

FIG. 3 is a sectional view along line A-A of FIG. 2.

FIG. 4 is a sectional view along line B-B- of FIG. 2.

FIG. 5 is a schematic view illustrating a punch is used to wash down a connecting section of the light sensor lead frame substrate in the present invention.

FIG. 6 is a schematic view illustrating the connecting section of the light sensor lead frame substrate in FIG. 5 is washed down by the punch in the present invention.

FIG. 7 is a partial enlarged drawing of the light sensor lead frame substrate of the present invention when the connecting sections are washed down.

FIG. 8 is a sectional view of a lead frame substrate of the light sensor lead frame substrate which is taken down from a metal substrate in the present invention.

FIG. 9 is a sectional view illustrating moisture in the air has to pass through a protruding edge before infiltrating into a reflector cup of the lead frame substrate of the light sensor lead frame substrate in the present invention.

FIG. 10 is a plan view illustrating moisture in the air infiltrates into the reflector cup of the lead frame substrate of the light sensor lead frame substrate in the present invention.

FIG. 11 is a prior art.

FIG. 12 is a prior art.

FIG. 13 is a prior art.

FIG. 14 is a prior art.

FIG. 15 is a prior art.

FIG. 16 is a prior art.

FIG. 17 is a prior art.

FIG. 18 is a prior art.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

In order to further understand the goal, characteristics and effect of the present invention, a number of embodiments along with the drawings are illustrated as following:

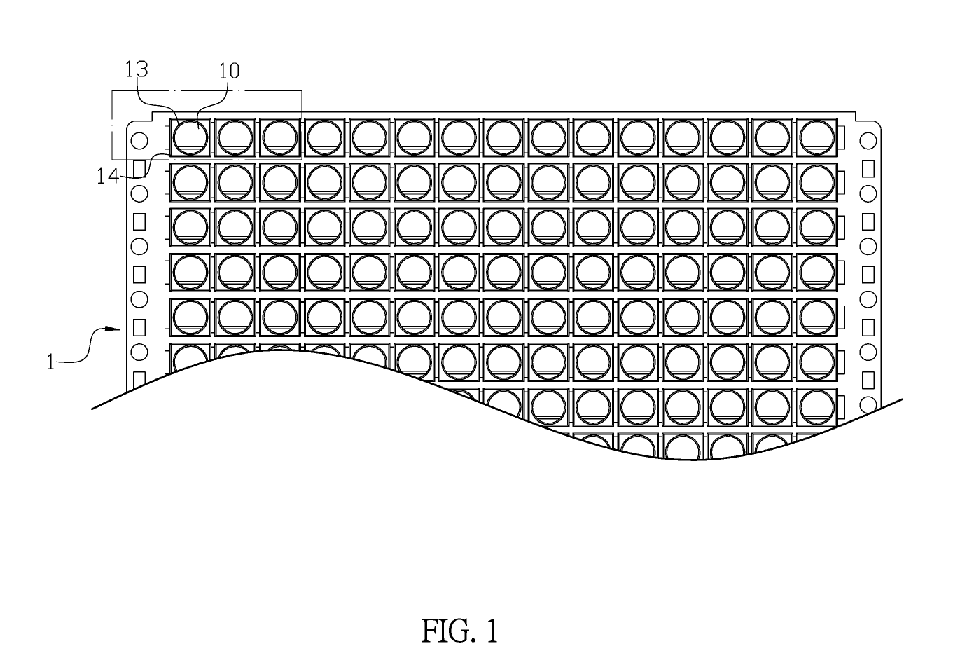

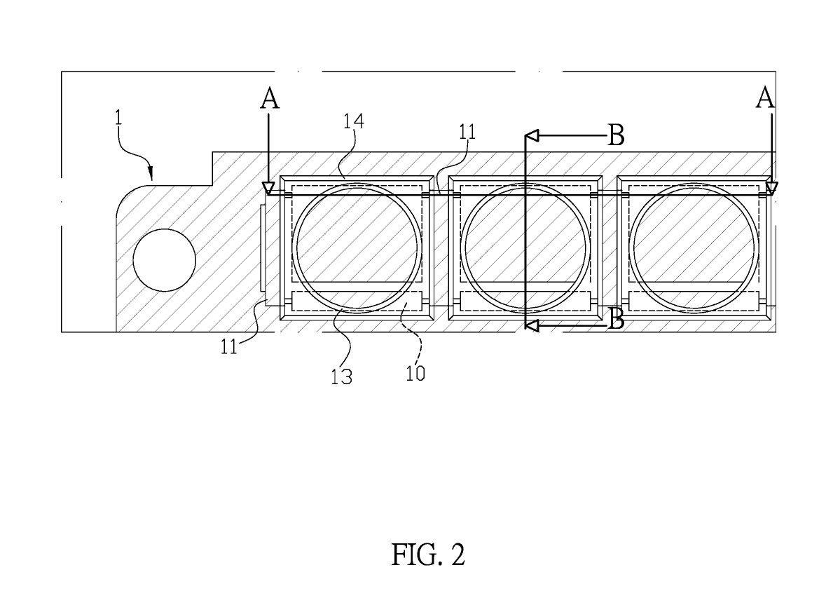

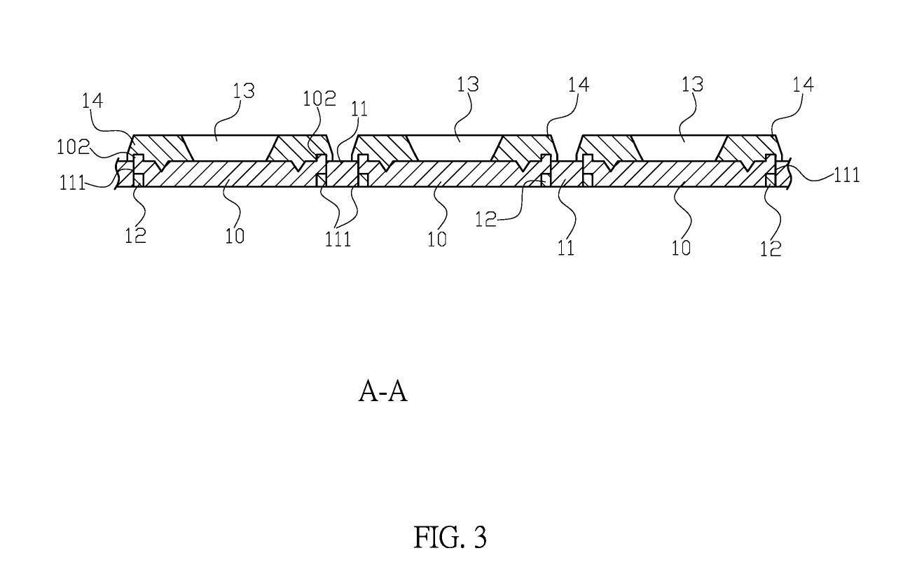

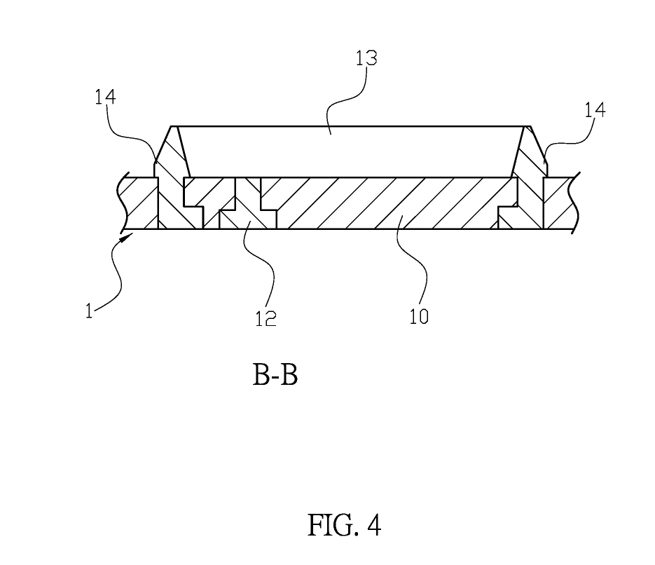

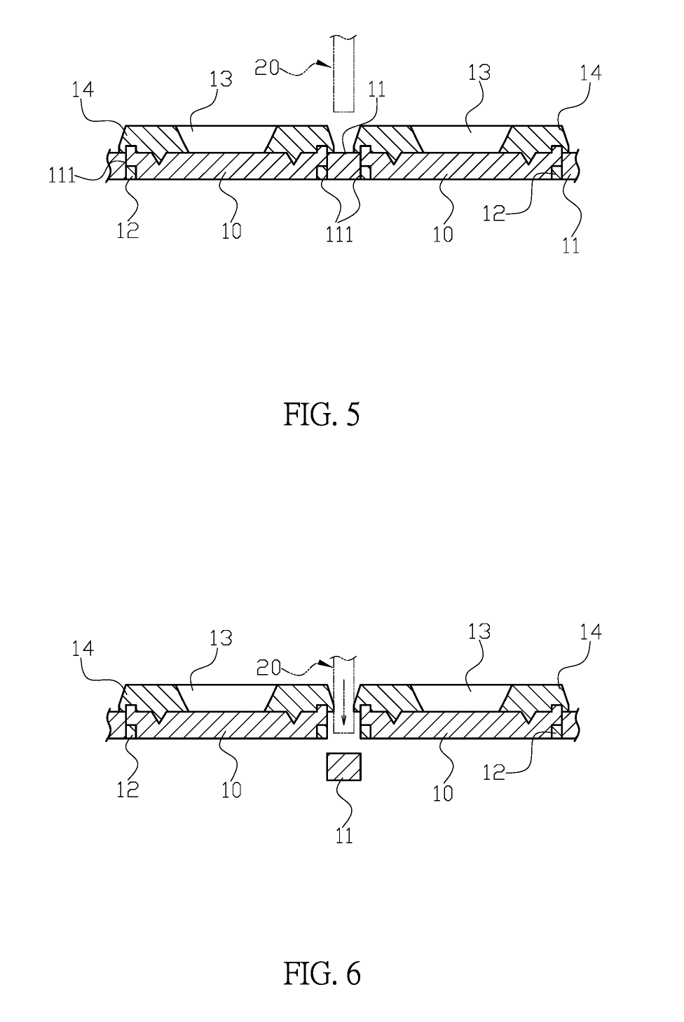

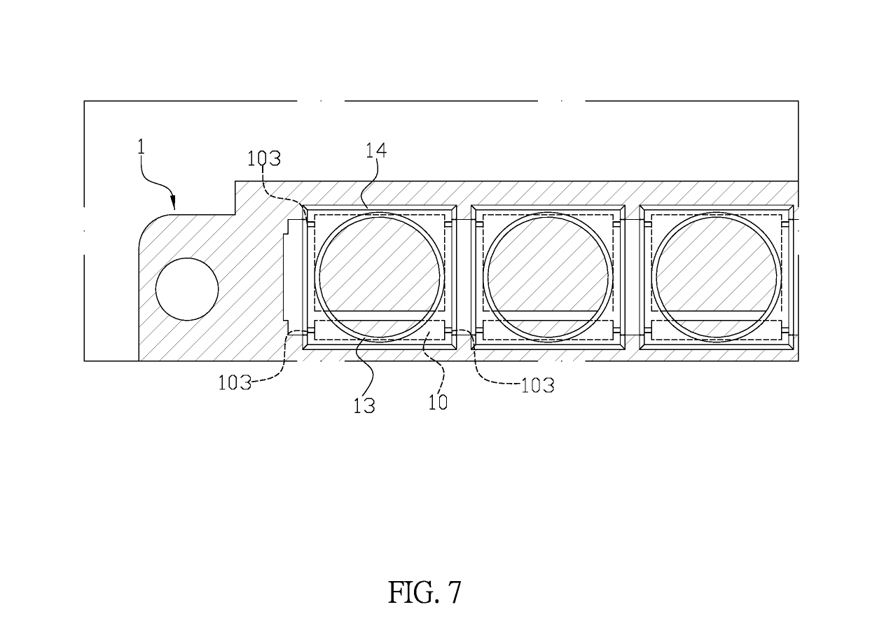

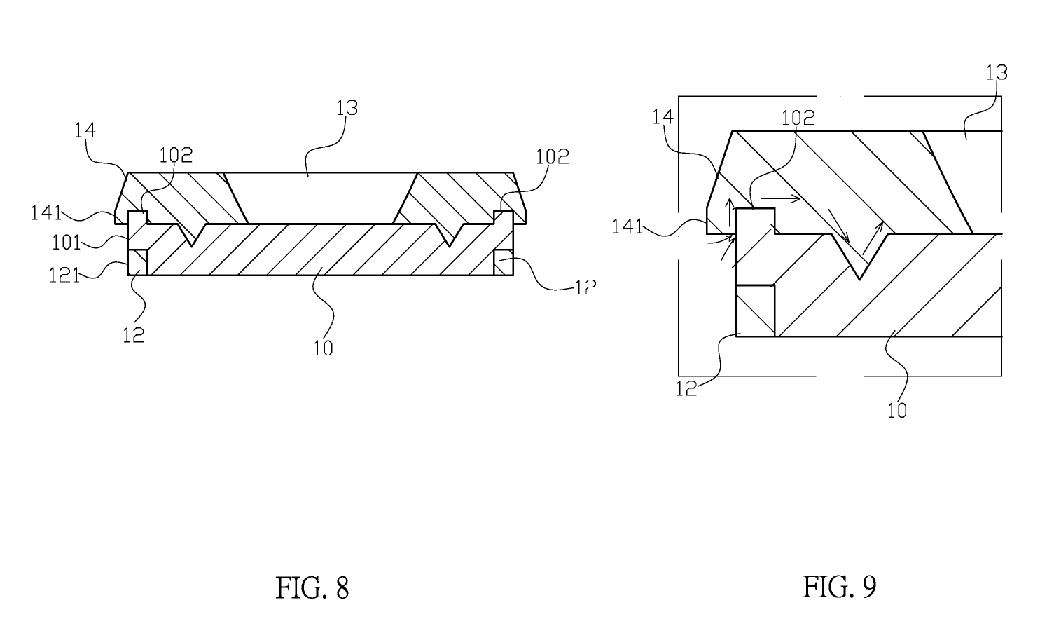

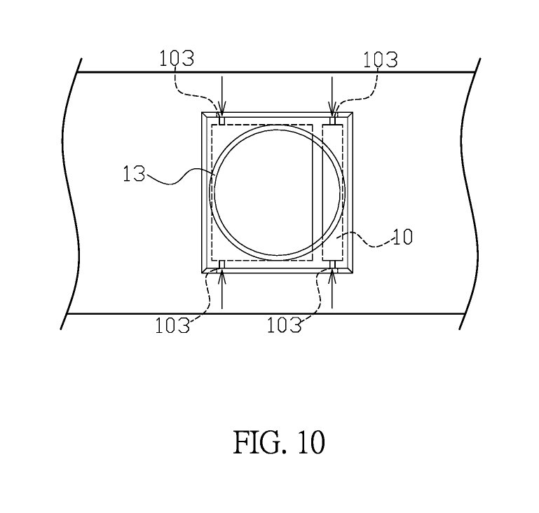

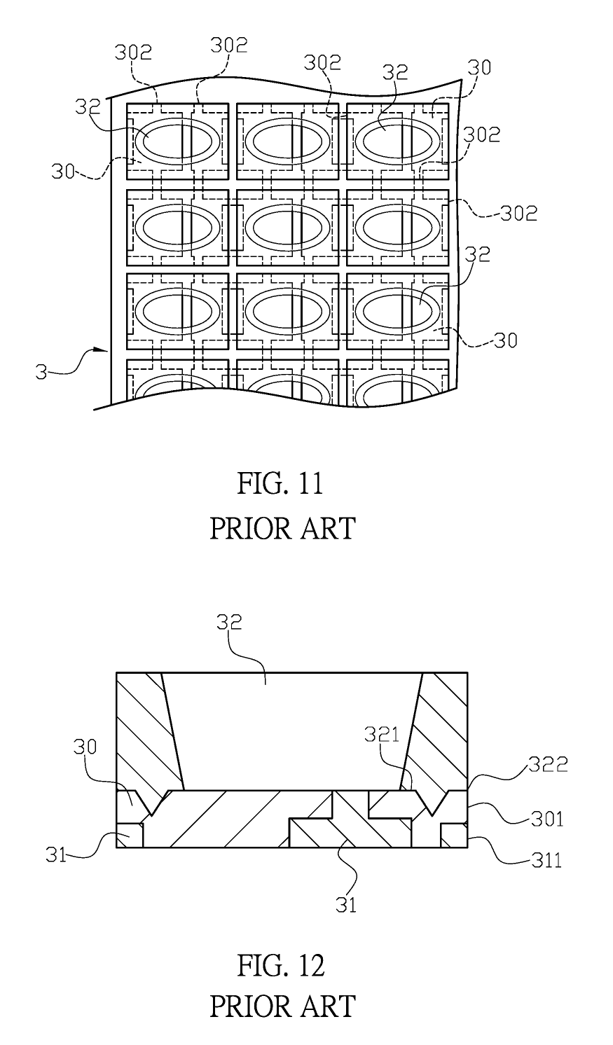

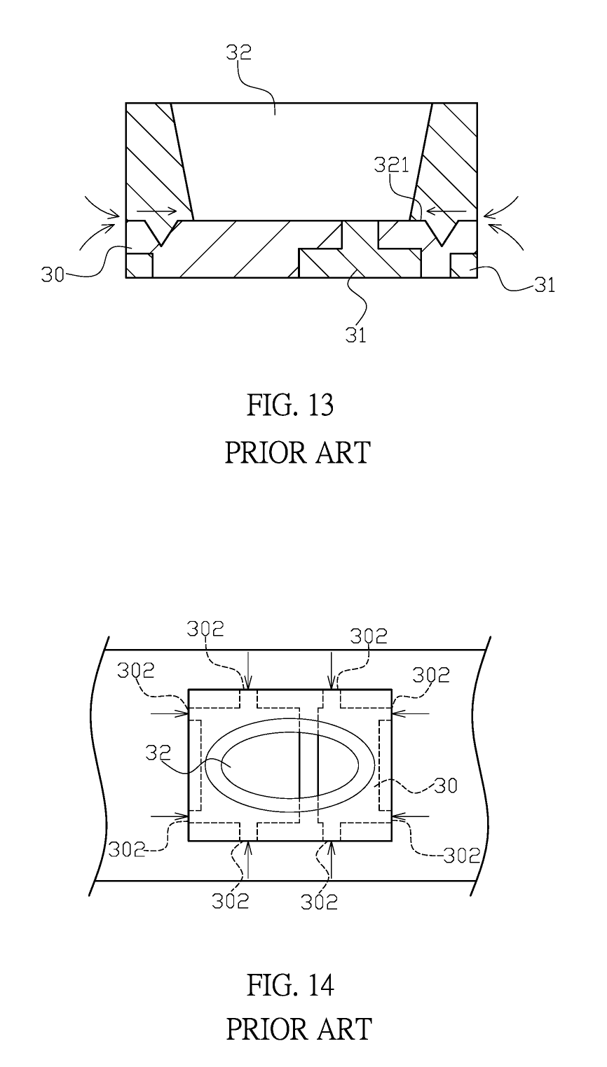

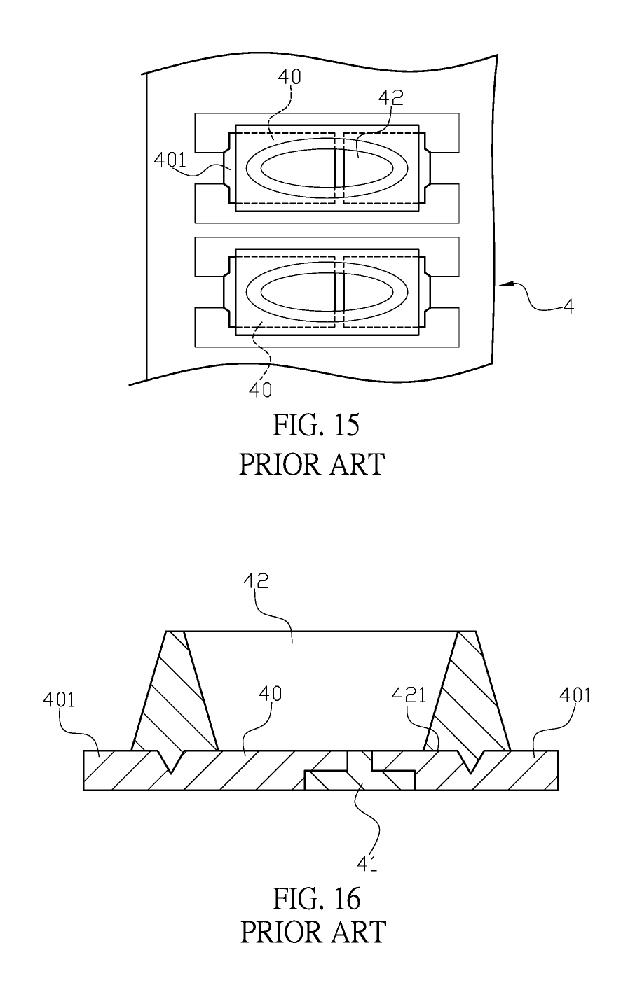

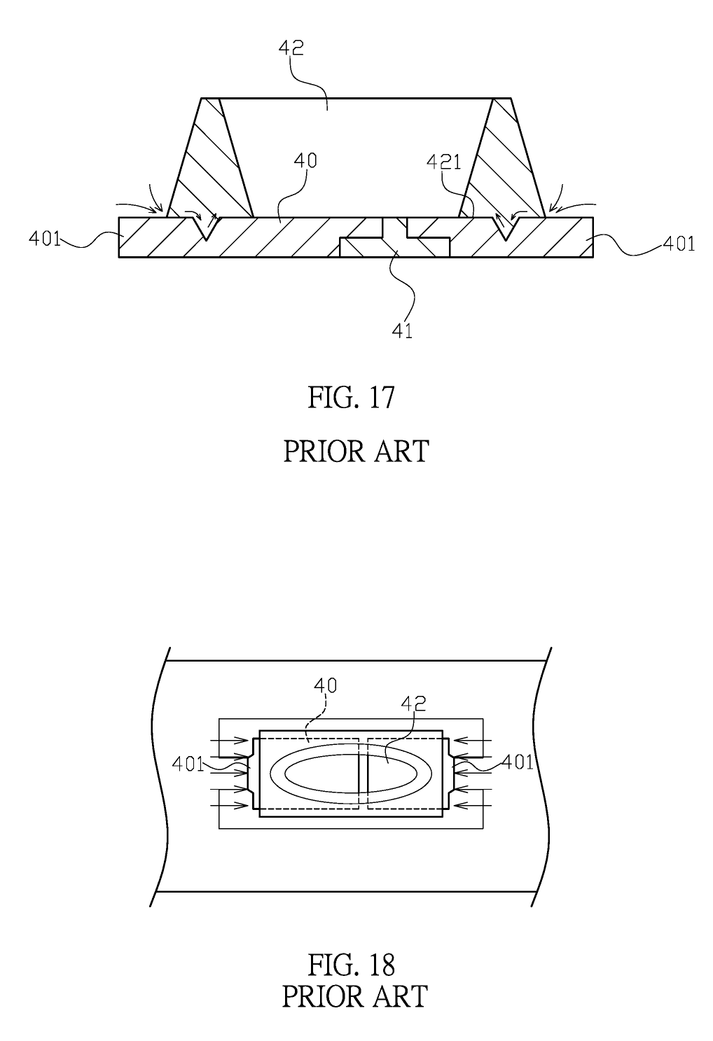

Referring to FIGS. 1 to 4, the present invention provides a light sensor lead frame substrate which comprises a plurality of lead frame substrates (10) formed on a metal substrate (1) through a series of processing including chemical etching, plasma etching and stamping. The lead frame substrates (10) are connected through a plurality of connecting sections (11), and each of the lead frame substrates (10) is connected to the metal substrate (1) through the connecting section (11). Moreover, each of the connecting sections (11) between the lead frame substrates (10) or between the lead frame substrate (11) and the metal substrate (1) has two pre-cut sections (111) respectively formed at two ends of the connecting section (11). Each of the lead frame substrates (10) comprises a first edge (101), and at least a protruding edge (102) upwardly protrudes from a top end of the first edge (101) (as shown in FIG. 8). After molding, the lead frame substrates (10) are configured to pass through a series of processing including electroplating, injection and desmear to enable each of the lead frame substrates (10) to have a first insulating layer (12), a reflector cup (13) and a second insulating layer (14), wherein the reflector cup (13) is adapted to cover the protruding edge (102) through the second insulating layer (14), and the second insulating layer (14) is configured to extend outwardly to partially cover top surfaces of adjacent connecting sections (11). Additionally, each of the second insulating layers (14) has a third edge (141) while each of the first insulating layers (12) comprises a second edge (121). Also, with the pre-cut sections (111), after the processing of electroplating, injection and desmear, the connecting sections (11) are adapted to be easily washed down by a punch (20) in the punching process (as shown in FIGS. 5 to 7). Furthermore, for the single lead frame substrate (10), with the second insulating layer (14) partially covering the top surfaces of the adjacent connecting sections (11), the third edge (141) of the second insulating layer (14) is configured to be formed non-coplanar to the first edge (101) of the lead frame substrate (10) and the second edge (121) of the first insulating layer (12) which are in the same plane (as shown in FIG. 8).

In one embodiment, the reflector cup (13) and the second insulating layer (14) of the lead frame substrate (10) are formed integrally.

In another embodiment, the first insulating layer (12), the reflector cup (13) and the second insulating layer (14) of the lead frame substrate (10) are made of engineering plastic.

In still another embodiment, the first insulating layer (12), the reflector cup (13) and the second insulating layer (14) of the lead frame substrate (10) are made of epoxy.

In a further embodiment, the first insulating layer (12), the reflector cup (13) and the second insulating layer (14) of the lead frame substrate (10) are made of silicone.

In still a further embodiment, the first insulating layer (12), the reflector cup (13) and the second insulating layer (14) of the lead frame substrate (10) are made of ceramic.

Comparing with conventional light sensor lead frame substrate, the present invention is advantageous because: (i) after the connecting sections (11) are washed down, each of the lead frame substrates (10) is weakly attached on the metal substrate (1) through the second insulating layer (14) thereof such that after the packaging, the lead frame substrates (10) are easily taken down from the metal substrate (1) through the punching processing or by fingers, which reduces the cost of production; (ii) after the connecting sections (11) are washed down, the lead frame substrates (10) are no longer connected, and each of the lead frame substrates (10) can be pre-tested before taken from the metal substrate (1), which increases the product yield; (iii) without clamping portions, the total number of the lead frame substrates (10) on the single metal substrate (1) is increased; (iv) the moisture in the air has to pass through the protruding edges (102) before infiltrating into the reflector cups (13) (as shown in FIG. 9), which prolongs the lifetime of the light sensor lead frame substrate; (v) each of the lead frame substrates (10) has no clamping portions and excess exposed metal portions (103), which effectively reduces the moisture in the air from infiltrating into the reflector cup (13), thereby prolonging the lifetime of the light sensor lead frame substrate (as shown in FIGS. 7 and 10); and (vi) without clamping portions, the packaging process of the light sensor lead frame substrate of the present invention can be completed by a common packaging equipment, which can be widely accepted by manufacturers.

Having described the invention by the description and illustrations above, it should be understood that these are exemplary of the invention and are not to be considered as limiting. Accordingly, the invention is not to be considered as limited by the foregoing description, but includes any equivalents.

What is claimed is:

1. A light sensor lead frame substrate comprising a plurality of lead frame substrates formed on a metal substrate through a series of processing including chemical etching, plasma etching and stamping; the lead frame substrates connected through a plurality of connecting sections, and each of the lead frame substrates connected to the metal substrate through the connecting section; each of the connecting sections between the lead frame substrates or between the lead frame substrate and the metal substrate having two pre-cut sections respectively formed at two ends of the connecting section; each of the lead frame substrates comprising a first edge, and at least a protruding edge upwardly protruding from a top end of the first edge; after molding, the lead frame substrates configured to pass through a series of processing including electroplating, injection and desmear to enable each of the lead frame substrates to have a first insulating layer, a reflector cup and a second insulating layer, and the reflector cup adapted to cover the protruding edge through the second insulating layer, and the second insulating layer configured to extend outwardly to partially cover top surfaces of adjacent connecting sections; each of the second insulating layers having a third edge while each of the first insulating layers comprising a second edge; with the pre-cut sections, after the processing of electroplating, injection and desmear, the connecting sections adapted to be easily washed down by a punch in the punching process, and, for the single lead frame substrate, with the second insulating layer partially covering the top surfaces of the adjacent connecting sections, the third edge of the second insulating layer configured to be formed non-coplanar to the first edge of the lead frame substrate and the second edge of the first insulating layer which are in the same plane.

2. The light sensor lead frame substrate of claim 1, wherein the reflector cup and the second insulating layer of the lead frame substrate are formed integrally.
